(19) United States
(12) Patent Application Publication
(10) Pub. No.: US 2025/0287754 A1
(43) Pub. Date: Sep. 11, 2025

(54) DISPLAY APPARATUS

(71) Applicant: Samsung Display Co., LTD., Yongin-si (KR)

(72) Inventor: Junhyeong Park, Yongin-si (KR)

(21) Appl. No.: 19/020,799

(22) Filed: Jan. 14, 2025

(30) Foreign Application Priority Data
Mar. 5, 2024 (KR) 10-2024-0031527

(51) Int. Cl. H10H 29/49; H10H 29/39; H10K 59/131; H10K 102/00

(52) U.S. Cl. CPC H10H 29/49; H10H 29/39; H10K 59/131; H10K 2102/311

(57) ABSTRACT

A display apparatus includes: a substrate; a first wiring on the substrate; and a second wiring on the first wiring and electrically connected to the first wiring, wherein the first wiring and the second wiring comprise an overlapping area in which the first wiring overlaps the second wiring in a plan view, and at least one of the first wiring or the second wiring comprises an opening in the overlapping area.

### CROSS-REFERENCE TO RELATED APPLICATION

The present application claims priority to and the benefit of Korean Patent Application No. 10-2024-0031527, filed on Mar. 5, 2024, in the Korean Intellectual Property Office, the entire disclosure of which is incorporated herein by reference.

### BACKGROUND

### 1. Field

Aspects of one or more embodiments relate to a structure of a display apparatus.

### 2. Description of the Related Art

As display apparatuses visually displaying electrical signals have been developed, various display apparatuses having excellent features such as being relatively thin, light weight, and having relatively low power consumption have been introduced. For example, flexible display apparatuses that may be folded or rolled have been introduced. Recently, studies regarding stretchable display apparatuses that may be modified in various forms have been actively in progress.

The above information disclosed in this Background section is only for enhancement of understanding of the background and therefore the information discussed in this Background section does not necessarily constitute prior art.

### SUMMARY

Aspects of one or more embodiments include a display apparatus that may secure an excellent stretchability. However, the one or more embodiments are only examples, and the scope of embodiments according to the present disclosure are not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first wiring on the substrate, and a second wiring on the first wiring and electrically connected to the first wiring, wherein the first wiring and the second wiring comprise an overlapping area in which the first wiring overlaps the second wiring in a plane, and at least one of the first wiring or the second wiring comprises an opening in the overlapping area.

According to one or more embodiments, the first wiring and the second wiring may be electrically connected to each other through a plurality of sub contact holes arranged in an area of the overlapping area excluding the opening.

According to one or more embodiments, the display apparatus may further include a first insulating layer arranged between the first wiring and the second wiring and a second insulating layer on the second wiring, wherein the first insulating layer may fill the opening of the first wiring and the second insulating layer may fill the opening of the second wiring.

According to one or more embodiments, the plurality of sub contact holes may penetrate the first insulating layer.

According to one or more embodiments, a sum of planar areas of the plurality of sub contact holes may be constant regardless of the number of the plurality of sub contact holes.

According to one or more embodiments, a sum of planar areas of the plurality of sub contact holes may be equal to a planar area of a contact hole to which the first wiring and the second wiring are electrically connectable without the opening.

According to one or more embodiments, the opening may have an elliptical, circular, or rhombus shape in a plane.

According to one or more embodiments, when the opening has an elliptical shape, the opening may be arranged such that a long axis of the elliptical shape is arranged in a direction in which a wiring defining the opening extends.

According to one or more embodiments, when the opening has a rhombus shape, the opening may be arranged such that a long diagonal of two diagonals of the rhombus shape is arranged in a direction in which a wiring defining the opening extends.

According to one or more embodiments, the first wiring may have a higher modulus than the second wiring.

According to one or more embodiments, each of the first wiring and the second wiring may include the opening in the overlapping area.

According to one or more embodiments, the first wiring may include the opening in the overlapping area and the second wiring may be integrally formed with the overlapping area without the opening.

According to one or more embodiments, the display apparatus may further include a plurality of pixel circuits on the substrate, a plurality of light-emitting elements respectively and electrically connected to the plurality of pixel circuits, and a bridge electrode connecting one of the plurality of light-emitting elements to one of the plurality of pixel circuits.

According to one or more embodiments, the first wiring may be arranged on the same layer as a source electrode or a drain electrode included in the plurality of pixel circuits, and the second wiring may be arranged on the same layer as the bridge electrode.

According to one or more embodiments, the first wiring may be electrically connected to one of the plurality of pixel circuits and the second wiring may electrically connect adjacent pixel circuits from among the plurality of pixel circuits.

According to one or more embodiments, a display apparatus includes a substrate, a first wiring on the substrate, an insulating layer on the first wiring, and a 1 second wiring on the insulating layer, wherein the first wiring and the second wiring include an overlapping area in which the first wiring overlaps the second wiring in a plane, the insulating layer includes an opening overlapping the overlapping area, and a connection material having a different modulus from each of the first wiring and the second wiring is arranged in the opening of the insulating layer.

According to one or more embodiments, the connection material may have a lower modulus than each of the first wiring and the second wiring.

According to one or more embodiments, the connection material may include a liquid metal.

According to one or more embodiments, the liquid metal may include eutectic gallium-indium alloy (EGaln) or gallium-indium-tin alloy (Galinstan).

According to one or more embodiments, the connection material may be in contact with an upper surface of the first wiring and a lower surface of the second wiring, and may electrically connect the first wiring to the second wiring.

According to one or more embodiments, the display apparatus may further include a plurality of pixel circuits on the substrate, a plurality of light-emitting elements respectively and electrically connected to the plurality of pixel circuits, and a bridge electrode connecting one of the plurality of light-emitting elements to one of the plurality of pixel circuits.

According to one or more embodiments, the first wiring may be arranged on the same layer as a source electrode or a drain electrode included in the plurality of pixel circuits, and the second wiring may be arranged on the same layer as the bridge electrode.

According to one or more embodiments, the first wiring may be electrically connected to one of the plurality of pixel circuits and the second wiring may electrically connect adjacent pixel circuits from among the plurality of pixel circuits.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic perspective view of a display apparatus according to some embodiments;

FIGS. 2A and 2B are perspective views showing a state in which the display apparatus of FIG. 1 is stretched in a first direction;

FIG. 2C is a perspective view showing a state in which the display apparatus of FIG. 1 is stretched in a second direction;

FIG. 2D is a perspective view showing a state in which the display apparatus of FIG. 1 is stretched in the first direction and the second direction;

FIG. 2E is a perspective view showing a state in which the display apparatus of FIG. 1 is stretched in a third direction;

FIG. 3 is a schematic plan view of a display apparatus according to some embodiments;

FIGS. 4A and 4B are plan views of a portion of a display area of a display apparatus according to some embodiments;

FIG. 5 is a cross-sectional view of a portion of a display apparatus according to some embodiments and may correspond to a cross-section of the display apparatus taken along the line Va-Va′ and line Vb-Vb′ of FIG. 4A;

FIG. 6 is an equivalent circuit schematically illustrating a pixel circuit and a light-emitting diode of FIG. 5;

FIGS. 7A to 7E are cross-sectional views schematically illustrating a light-emitting diode of a display apparatus according to some embodiments;

FIG. 8 is a plan view of a portion of a display area of a display apparatus according to some embodiments;

FIG. 9 is an enlarged plan view of a portion of the display apparatus according to some embodiments and corresponds to area A of FIG. 8;

FIG. 10 is a cross-sectional view of a portion of a display apparatus according to some embodiments and corresponds to a cross-section of the display apparatus taken along the line I-I′ of FIG. 8 and the line II-II′ of FIG. 9;

FIG. 11 is a plan view of a portion of a display apparatus according to some embodiments;

FIG. 12 is an enlarged plan view of a portion of a display apparatus according to some embodiments and corresponds to area B of FIG. 11;

FIG. 13 is an enlarged plan view of a portion of the display apparatus according to some embodiments;

FIG. 14 is an enlarged plan view of a portion of a display apparatus according to some embodiments;

FIG. 15 is a cross-sectional view of a portion of a display apparatus according to some embodiments and corresponds to a cross-section of the display apparatus taken along the line I-I′ of FIG. 8 and line III-III′ of FIG. 14; and

FIGS. 16A to 16G are perspective views schematically illustrating embodiments of an electronic device including a display apparatus according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Because the disclosure may have diverse modified embodiments, aspects of some embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

One or more embodiments of the disclosure will be described below in more detail with reference to the accompanying drawings. Those elements that are the same or are in correspondence are rendered the same reference numeral regardless of the figure number, and redundant descriptions thereof are omitted.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

In the drawings, for convenience of description, sizes of components may be exaggerated or reduced. In other words, because sizes and thicknesses of elements in the drawings are arbitrarily illustrated for convenience of description, the following embodiments are not limited thereto.

When a certain embodiment may be implemented differently, a specific process order may be performed differently from the described order. For example, two consecutively described processes may be performed substantially at the same time or performed in an order opposite to the described order.

In the specification, the expression “A and/or B” may indicate A, B, or A and B. Also, the expression “at least one of A and B” may indicate A, B, or A and B. In the embodiments hereinafter, it will be understood that when an element,

an area, or a layer is referred to as being connected to another element, area, or layer, it can be directly and/or indirectly connected to the other element, area, or layer. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

In the following examples, the x-axis, the y-axis, and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

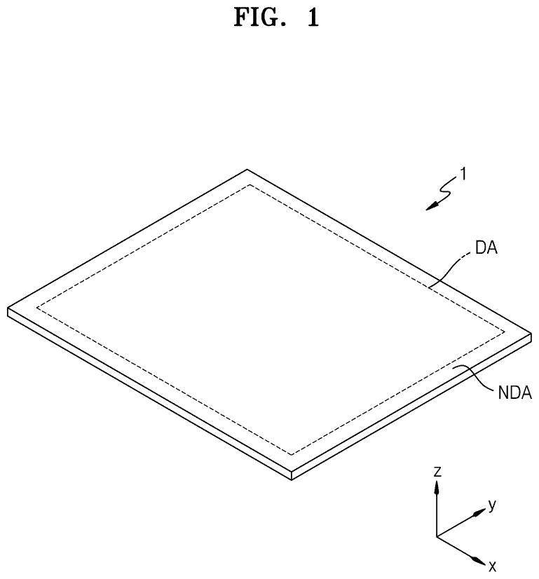

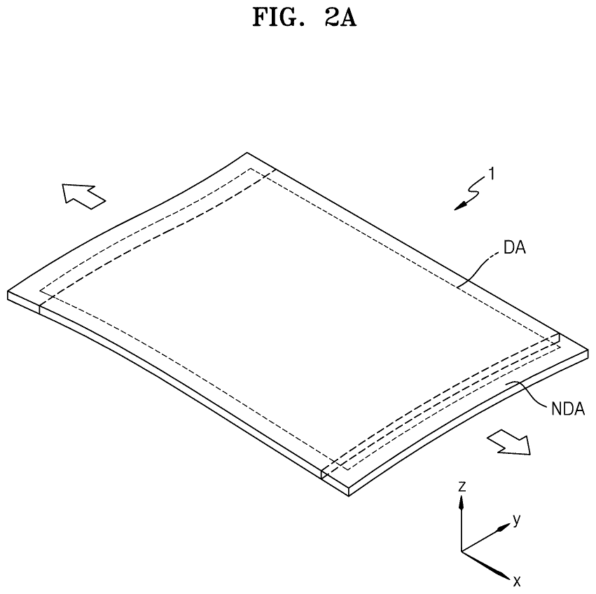

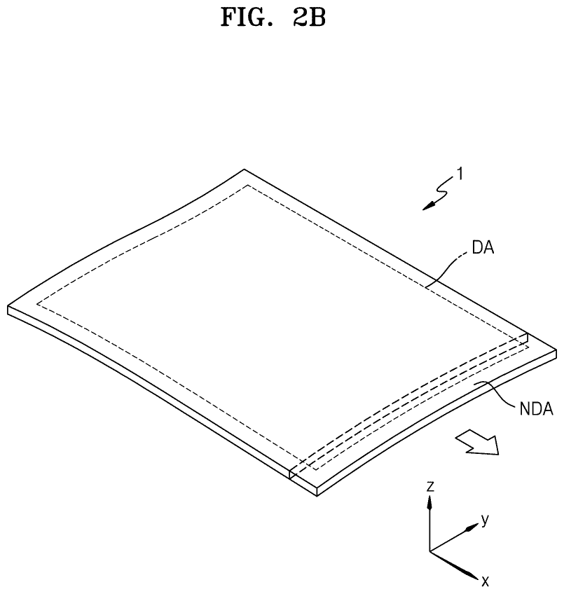

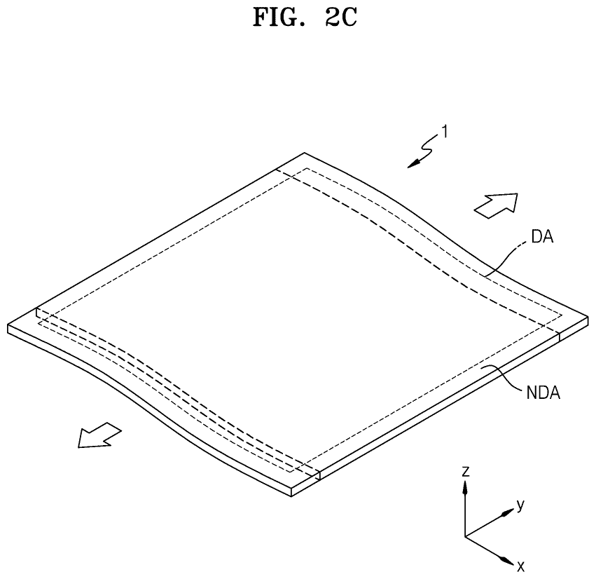

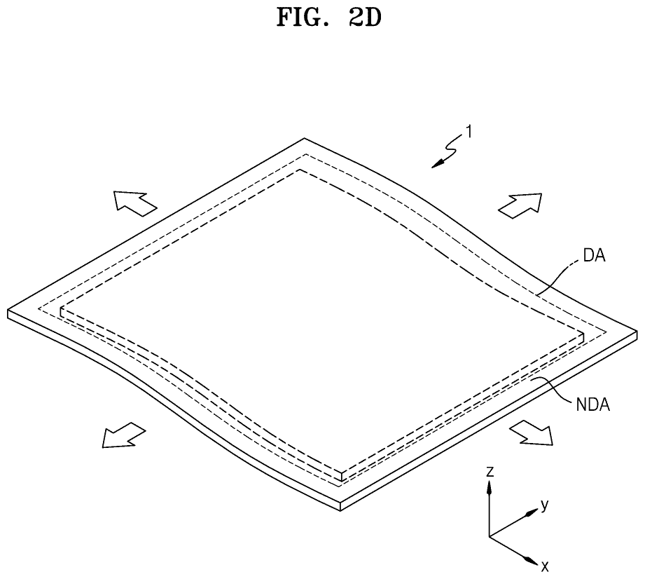

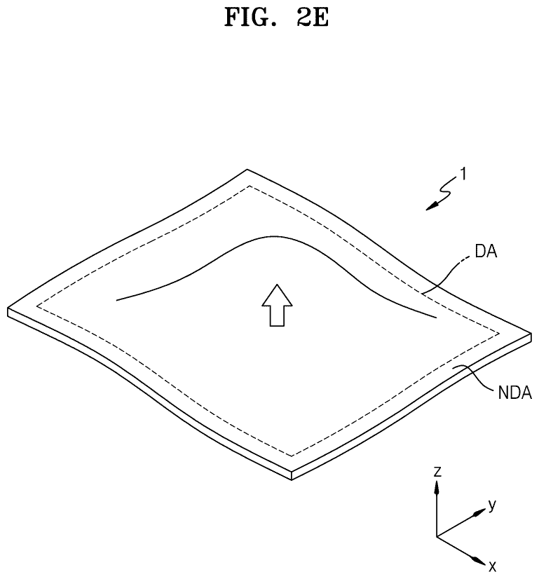

FIG. 1 is a schematic perspective view of a display apparatus 1 according to some embodiments. FIGS. 2A and 2B are perspective views showing a state in which the display apparatus 1 of FIG. 1 is stretched in a first direction. FIG. 2C is a perspective view showing a state in which the display apparatus 1 of FIG. 1 is stretched in a second direction. FIG. 2D is a perspective view showing a state in which the display apparatus 1 of FIG. 1 is stretched in the first direction and the second direction. FIG. 2E is a perspective view showing a state in which the display apparatus 1 of FIG. 1 is stretched in a third direction.

Referring to FIG. 1, the display apparatus 1 may include a display area DA and a non-display area NDA. The display area DA may include a plurality of pixels. The display apparatus 1 may provide an image (e.g., a predetermined image) by using light emitted from the plurality of pixels. The non-display area NDA may be arranged outside (e.g., in a periphery or outside a footprint of) the display area DA. The entire display area DA may be surrounded by the non-display area NDA.

The display apparatus 1 may be stretched or contracted in various directions. The display apparatus 1 may be stretched in the first direction (e.g., an x direction and/or a-x direction) by an external force applied by an external object or a user. According to some embodiments, as shown in FIGS. 2A and 2B, the display area DA and/or the non-display area NDA of the display apparatus 1 may be stretched in the first direction (e.g., an x direction and/or a −x direction). For example, as shown in FIG. 2A, the display area DA and/or the non-display area NDA may be stretched in the x and −x directions or may be stretched in the x direction while one side of the display apparatus 1 is fixed, as shown in FIG. 2B.

The display apparatus 1 may be stretched in the second direction (e.g., a y direction and/or a-y direction) by an external force applied by an external object or a user. According to some embodiments, as shown in FIG. 2C, the display area DA and/or the non-display area NDA of the display apparatus 1 may be stretched in the y direction and the-y direction. In some embodiments, the display apparatus 1 may be stretched in the y direction or the −y direction while one side thereof is fixed.

The display apparatus 1 may be stretched in a plurality of directions, such as the first direction (e.g., the x direction and/or the-x direction) and the second direction (the y direction and/or the −y direction), by an external force applied by an external object or a part of the body of a person. As shown in FIG. 2D, the display area DA and/or the non-display area NDA of the display apparatus 1 may be stretched in the +x directions and ty directions.

The display apparatus 1 may be stretched in the third direction (e.g., a z direction and/or a-z direction) by an external force applied by an external object or a part of the body of a person. According to some embodiments, FIG. 2E shows a portion of the display apparatus 1, such as a portion of the display area DA, protruding in the z direction. In some embodiments, a portion of the display apparatus 1, such as a portion of the display area DA, may protrude in the z direction (or be submerged in the-z direction).

FIGS. 2A to 2E show the display apparatus 1 increased in the first direction, the second direction, and/or the third direction, but embodiments according to the present disclosure are not limited thereto. In some embodiments, the display apparatus 1 may be variously modified in atypical shapes, such as being bent or twisted along two or more axes.

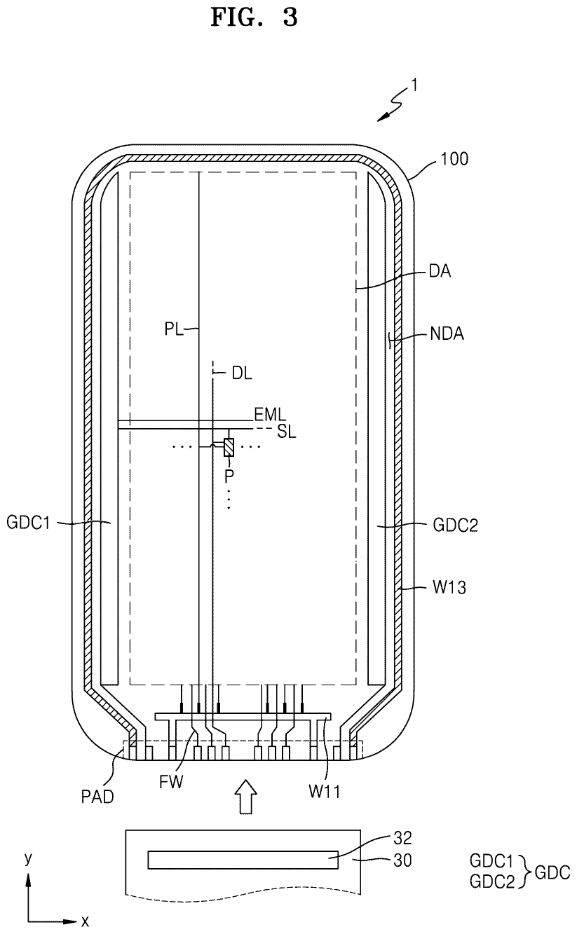

FIG. 3 is a schematic plan view of a display apparatus 1 according to some embodiments.

Referring to FIG. 3, various components included in the display apparatus 1 are located on the substrate 100. The substrate 100 may include the display area DA and the non-display area NDA surrounding (e.g., in a periphery or outside a footprint of) the display area DA. The display area DA may be covered with a protective layer and be protected from outside air or moisture.

Pixels P are arranged in the display area DA of the substrate 100. The pixels P may each show an image by using light emitted from a light-emitting element such as a light emitting diode. Each light-emitting diode may emit, for example, red, green, or blue light. Although a single pixel P is illustrated in FIG. 3, as a person having ordinary skill in the art would recognize, the display area DA may include any suitable number of pixels according to the design and size of the display apparatus 1.

Each light-emitting diode may be electrically connected to a pixel circuit and each pixel circuit may include transistors and a storage capacitor. Each pixel may be electrically connected to peripheral circuits arranged in the non-display area NDA. The peripheral circuits arranged in the non-display area NDA may include a gate drive circuit GDC and a terminal portion PAD.

The gate drive circuit GDC may include drivers for providing electrical signals to a gate electrode of each of the transistors that are electrically connected to the light-emitting elements. For example, the gate drive circuit GDC may apply a scan signal to each of the pixel circuits corresponding to the pixels P through the scan line SL. In addition, the gate drive circuit GDC may apply an emission control signal to each pixel circuit through an emission control line EML.

The gate drive circuit GDC may include a first gate drive circuit GDC1 and a second gate drive circuit GDC2 arranged on both sides with the display area DA therebetween. The second gate drive circuit GDC2 may be arranged on an opposite side of the first gate drive circuit GDC1 with respect to the display area DA and may be approximately parallel to the first gate drive circuit GDC1. Some of the pixel circuits may be electrically connected to the first gate drive circuit GDC1 and the others may be electrically connected to the second gate drive circuit GDC2. In some embodiments, the second gate drive circuit GDC2 may be omitted.

The terminal portion PAD may be arranged on one side of the substrate 100. The terminal portion PAD may be exposed without being covered by an insulating layer and be connected to a display circuit board 30. A display driver 32 may be arranged in the display circuit board 30.

The display driver 32 may generate a control signal transmitted to the first gate drive circuit GDC1 and the second gate drive circuit GDC2. The display driver 32 may generate a data signal and the generated data signal may be transmitted to the pixel circuit of the pixels P through a fanout wiring FW and a data line DL connected to the fanout wiring FW.

The display driver 32 may supply a first power voltage VDD to a driving voltage supply wiring W11 and a second power voltage VSS to a common voltage supply wiring W13. The first power voltage VDD may be applied to the pixel circuit of the pixel P through the driving voltage line PL connected to the driving voltage supply wiring W11 and the second power voltage VSS may be applied to a counter electrode (or a second electrode) of a light-emitting element connected to the common voltage supply wiring W13. The driving voltage supply wiring W11 may extend in the x direction from a lower side of the display area DA. The common voltage supply wiring W13 may have a loop shape with one open side and thus partially surround the display area DA.

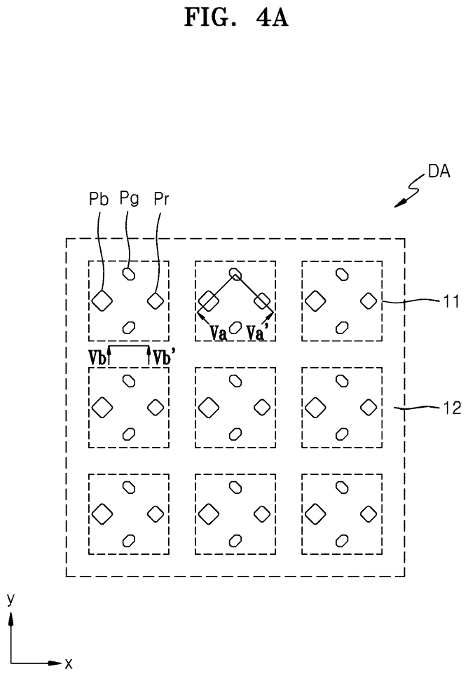

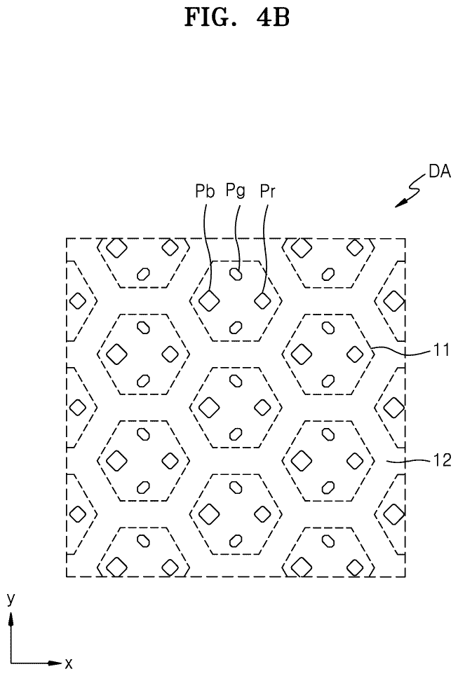

FIGS. 4A and 4B are plan views of a portion of the display area DA of the display apparatus 1 according to some embodiments.

Referring to FIGS. 4A and 4B, the display area DA may include first areas 11 and a second region 12 between the first areas 11. The first area 11 is a kind of a unit pixel and may include pixels emitting different light from each other.

In some embodiments, FIGS. 4A and 4B show that the pixels have an array of a diamond pentile® in the display area DA and each of the unit pixels includes one blue pixel Pb, one red pixel, and two green pixels Pg. Unit pixels may be a minimum repeated unit of pixels having an array (e.g., a set or predetermined array) and, in some embodiments, the pixels may have a variety of arrangements, such as a striped type arrangement, and each of the unit pixels may include one blue pixel Pb, one red pixel Pr, and one green pixel Pg.

The first area 11 may have a polygonal shape on a plane, such as having a quadrilateral shape as shown in FIG. 4A or a hexagonal shape as shown in FIG. 4B. The second area 12, which is an area between the first areas 11, may be a signal line providing a signal (e.g., a scan line, a data line, etc.) or an area through which a voltage line passes.

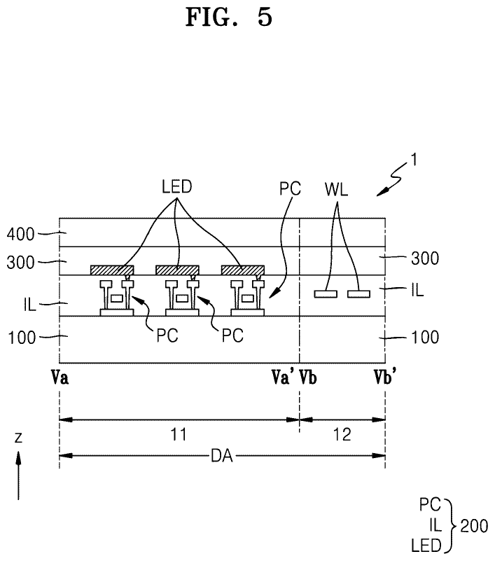

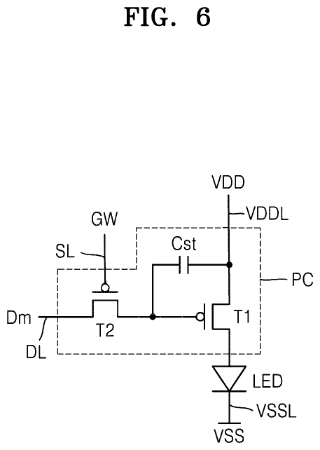

FIG. 5 is a cross-sectional view of a portion of the display area DA of the display apparatus 1 according to some embodiments, taken along the line Va-Va′ and line Vb-Vb′ of FIG. 4A, and FIG. 6 is an equivalent circuit diagram schematically illustrating a pixel circuit and a light-emitting diode LED of FIG. 5.

Referring to FIG. 5, the display apparatus 1 may include a display layer 200, a protective layer 300, and a touch layer 400 on the substrate 100. The substrate 100 may include a stretchable material such as a stretchable polymer resin. In some embodiments, the substrate 100 may include an elastomer. The elastomer may include an organic elastomer, an organic-inorganic elastomer, or a combination thereof. For example, the substrate 100 may include a silicon-based elastomer such as polydimethylsiloxane, a styrene-based elastomer, an olefin-based elastomer, polyurethane, or a mixture thereof. The substrate 100 may have a single-layer or multilayer structure.

The display layer 200 may include a pixel circuit PC arranged in the first area 11 and a light-emitting element, such as light-emitting diode LED, electrically connected to the pixel circuit PC. The pixel circuit PC may include a transistor.

According to some embodiments, as shown in FIG. 6, the pixel circuit PC may include a first transistor T1, a second transistor T2, and a storage capacitor Cst. The pixel circuit PC may be electrically connected to the signal line and the voltage line. The signal line may include a scan line SL and a data line DL and the voltage line may include a first voltage line VDDL and a second voltage line VSSL.

The second transistor T2 may be electrically connected to the scan line SL and the data line DL. The scan line SL may provide a scan signal GW to a gate electrode of the second transistor T2. The second transistor T2 may transmit the data signal Dm input from the data line DL to the first transistor T1 according to the scan signal GW input from the scan line SL.

The storage capacitor Cst may be electrically connected to the second transistor T2 and the first voltage line VDDL and may be store a voltage corresponding to a difference between a voltage received from the second transistor T2 and the first power voltage VDD provided by the first voltage line VDDL.

The first transistor T1 is a driving transistor that may control the driving current flowing through the light-emitting diode LED. The first transistor T1 may be connected to the first voltage line VDDL and the storage capacitor CST. The first transistor T1 may control a driving current flowing from the first voltage line VDDL through the light-emitting diode LED in correspondence with a voltage value stored in the storage capacitor Cst. The light-emitting diode LED may emit light having a certain brightness according to the driving current. The first electrode of the light-emitting diode LED may be electrically connected to the first transistor T1 and the second electrode may be electrically connected to the second voltage line VSSL supplying the second power voltage VSS.

Referring again to FIG. 5, the display layer 200 may include an insulating layer IL arranged between components (semiconductor layers, electrodes, etc.) of the pixel circuit PC and/or between the pixel circuit PC and the light-emitting diode LED.

The signal line (e.g., the scan line, the data line, etc.) and/or the voltage line

(e.g., the first voltage line, the second voltage line, etc.) electrically connected to the transistor of the pixel circuit PC may be electrically connected to the pixel circuit PC arranged in the first area 11 and, in this regard, FIG. 5 illustrates a connection wiring WL. The connection wiring WL described above may correspond to the signal line (e.g., the scan line, the data line, etc.) and/or the voltage line (e.g., the first voltage line, the second voltage line, etc.).

The protective layer 300 may be located on the light-emitting diode LED and may protect the light-emitting diode LED from external force and/or moisture. The protective layer 300 may include an inorganic protective layer and/or an organic protective layer. In some embodiments, the protective layer 300 may have a structure in which an inorganic protective layer including an inorganic insulating material, an organic protective layer including an organic insulating material, and an inorganic protective layer including an inorganic insulating material are stacked.

In some embodiments, the protective layer 300 may include an organic material such as resin and may be a single layer including the above organic material. In some embodiments, the protective layer 300 may include urethane epoxy acrylate. The protective layer 300 may include a photosensitive material, such as a photoresist.

The touch layer 400 may be located on the protective layer 300. The touch layer 400 may include touch electrodes and touch insulating layers respectively located below and above the touch electrodes.

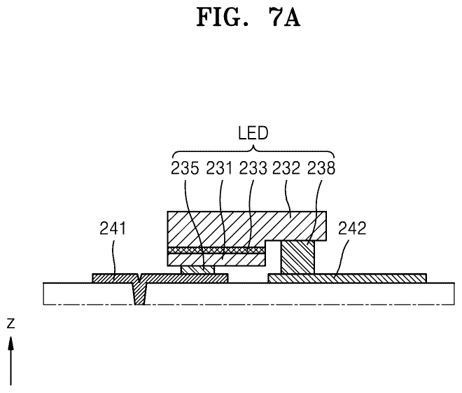

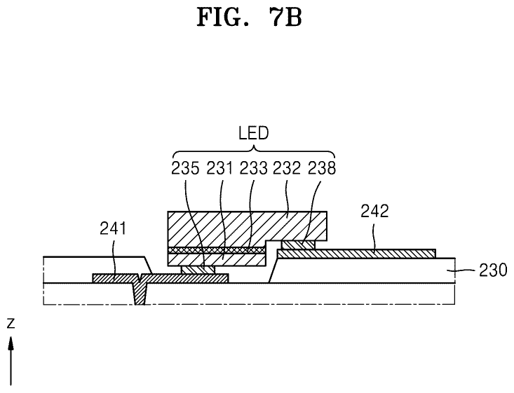

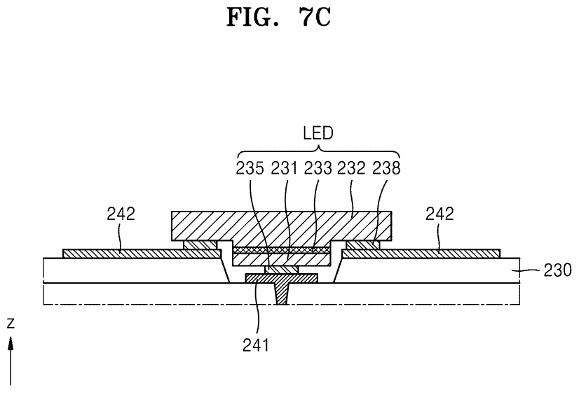

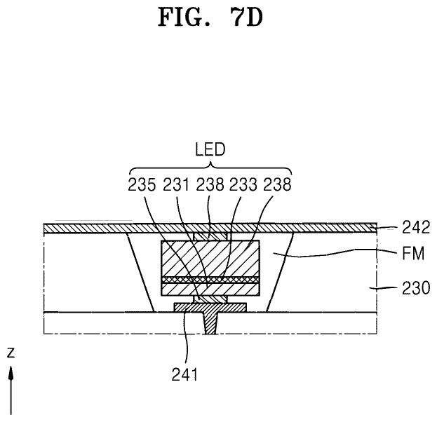

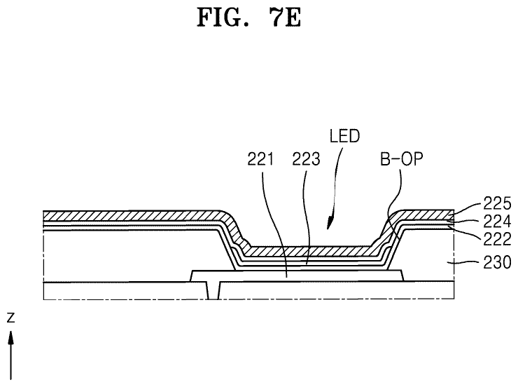

FIGS. 7A to 7E are cross-sectional views schematically illustrating the light-emitting diode LED of the display apparatus according to some embodiments.

Referring to FIG. 7A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively and electrically connected to a first electrode pad 241 and a second electrode pad 242 that are arranged on the same layer. The second electrode pad 242 may be a portion of the second voltage line VSSL described with reference to FIG. 6 or may be a conductive layer electrically connected to the second voltage line VSSL.

In some embodiments, the first semiconductor layer 231 may include a p-type semiconductor layer. The p-type semiconductor layer may be selected from a semiconductor material having a composition formula of InxAlyGa1-x-yN (0≤x≤1, 0≤y≤1, 0≤x+y≤1), for example, GaN, AlN, AlGaN, InGaN, InN, InAIGaN, AllnN, etc. and may be doped with a p-type dopant such as Mg, Zn, Ca, Sr, Ba, etc.

The second semiconductor layer 232 may include, for example, an n-type semiconductor layer. The n-type semiconductor layer may be selected from a semiconductor material having a composition formula of InxAlyGa1-x-yN (0≤x≤1, 0≤y≤1, 0≤x+y≤1), for example, GaN, AlN, AlGaN, InGaN, InN, InAlGaN, AlInN, etc. and may be doped with an n-type dopant such as Si, Ge, Sn, etc.

The intermediate layer 233 is an area in which electrons and holes are recombined and, as the electrons and holes are recombined, an energy level may be transitioned to a low energy level and light having a wavelength corresponding to the low energy level may be generated. The intermediate layer may, for example, be formed by including a semiconductor material having a composition formula of InxAlyGa1-x-yN (0≤x≤1, 0≤y≤1, 0≤x+y≤1) and may be formed in a single quantum well structure or a multi quantum well (MQW) structure. In addition, the intermediate layer may include a quantum wire structure or a quantum dot structure.

FIG. 7A illustrates that the first semiconductor layer 231 includes a p-type semiconductor layer and the second semiconductor layer 232 includes an n-type semiconductor layer, but the disclosure is not limited thereto. In some embodiments, the first semiconductor layer 231 may include an n-type semiconductor layer and the second semiconductor layer 232 may include a p-type semiconductor layer.

FIG. 7A illustrates that the first electrode pad 241 and the second electrode pad 242 are arranged on the same layer, but the disclosure is not limited thereto. Referring to FIG. 7B, the first electrode pad 241 and the second electrode pad 242 may be arranged on different layers from each other. For example, a bank layer 230 having an opening overlapping at least a portion of the first electrode pad 241 may be located on the first electrode pad 241 and the second electrode pad 242 may be located on the bank layer 230. A structure of the light-emitting diode LED shown in FIG. 7B is as described with reference to FIG. 7A.

In some embodiments, as shown in FIG. 7C, the second electrode pad 242 may be arranged on both sides of the first electrode pad 241 in a cross-sectional view. The bank layer 230 may include an opening overlapping at least a portion of the first electrode pad 241 and the second electrode pad 242 may be arranged around the opening of the bank layer 230. In some embodiments, the second electrode pad 242 may have a closed loop shape surrounding the entire opening of the bank layer 230 and/or the entire first electrode pad 241. The structure of the light-emitting diode LED shown in FIG. 7C is as described with reference to FIG. 7A.

FIGS. 7A to 7C illustrate that the first electrode 235 and the second electrode 238 of the light-emitting diode LED face the same direction (e.g., a downward direction, the-z direction), but the disclosure is not limited thereto. As shown in FIG. 7D, the first electrode 235 and the second electrode 238 of the light-emitting diode LED may face opposite directions from each other.

The bank layer 230 may include an opening exposing at least a portion of the first electrode pad 241 and the thickness of the bank layer 230 may be substantially the same as the thickness of the light-emitting diode LED. The opening of the bank layer 230 may be filled with a filling material FM and the second electrode pad 242 may be located on the bank layer 230 to be electrically connected (e.g., in contact) with the second electrode 238 of the light-emitting diode LED. The filling material FM may be an organic material with insulation.

Referring to FIG. 7E, the light-emitting diode LED may include an organic light-emitting diode including an organic material. The organic light-emitting diode LED may include a first electrode 221, a second electrode 225 facing the first electrode 221, and an emission layer 223 between the first electrode 221 and the second electrode 225. A first functional layer 222 may be arranged between the first electrode 221 and the emission layer 223 and a second functional layer 224 may be arranged between the emission layer 223 and the second electrode 225.

An edge of the first electrode 221 may be covered with the bank layer 230 including an insulating material. The bank layer 230 may include an opening B-OP overlapping a center of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In some embodiments, the first electrode 221 may include a reflective layer including silver (Ag), magnesium (Mg), aluminum (Al), platinum (Pt), palladium (Pd), silver (Au), nickel (Ni), neodymium (Nd), iridium (Ir), chromium (Cr), or a compound thereof. In some embodiments, the first electrode 221 may further include a layer including ITO, IZO, ZnO, AZO, or In₂O₃ above/below the reflective layer described above.

The emission layer 223 may include a high molecular-weight or low molecular-weight organic material emitting a color of light (e.g., a set or predetermined color of light). The first functional layer 222 may include a hole transport layer (HTL) and/or a hole injection layer (HIL). The second functional layer 224 may include an electron transport layer (ETL) and/or an electron injection layer (EIL).

An second electrode 225 may include a conductive material having a low work function. For example, the second electrode 225 may include a transparent (or transflective) layer including Ag, Mg, Al, Pt, Pd, Au, Ni, Nd, Ir, Cr, lithium (Li), calcium (Ca), or an alloy thereof. Alternatively, the second electrode 225 may further include a layer, such as ITO, IZO, ZnO, AZO, or In₂O₃, on the transparent (or transflective) layer including the material described above.

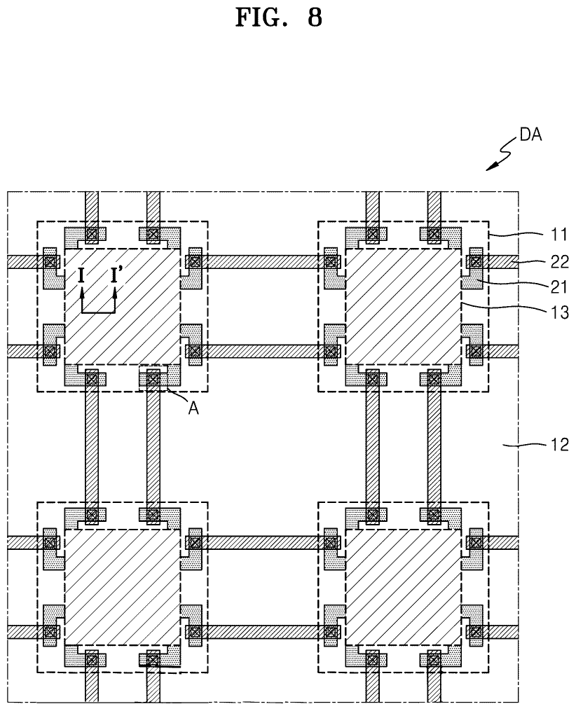

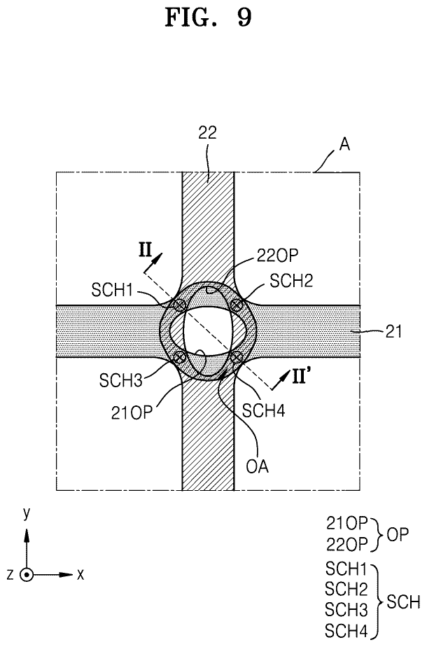

FIG. 8 is a plan view of a portion of the display area of the display apparatus according to some embodiments. FIG. 9 is an enlarged plan view of a portion of the display apparatus according to some embodiments and corresponds to area A of FIG. 8.

Referring to FIG. 8, the display area DA may include the first areas 11 and the second area 12 between the first areas 11. As described above, the first area 11 is a kind of a unit pixel and may include pixels emitting different light from each other. For example, according to some embodiments, the first area 11 may include one blue pixel, one red pixel, and two green pixels.

The plurality of pixels may each include the pixel circuit PC (refer to FIG. 6) and the light-emitting diode LED connected thereto. Thus, a plurality of pixel circuits PC included in each of the plurality of pixels may be arranged in the first area 11. In this case, the area in which the plurality of pixel circuits PC are arranged may be referred to as a pixel circuit area 13.

The second area 12 surrounds the plurality of first areas 11 may be the remaining area excluding the first area 11 of the display area DA. The second area 12 is an area in which the plurality of pixels are not arranged and the pixel circuit or the light-emitting element may not be arranged. However, the second area 12 is an area in which the connection wiring WL (refer to FIG. 5) connecting adjacent pixels among the plurality of pixels are arranged. The connection wiring WL (FIG. 5) may connect adjacent pixel circuits from among the plurality of pixel circuits.

In particular, a first wiring 21 and a second wiring 22 located on the first wiring 21 may be arranged in the display area DA. The first wiring 21 is a wiring arranged in the first area 11 and may be electrically connected to any one of the plurality of pixel circuits PC (refer to FIG. 6) in the pixel circuit area 13.

The second wiring 22 may be arranged in the second area 12 and may electrically connect unit pixels adjacent to each other. In particular, an end of the second wiring 22 may be connected to the first wiring 21 arranged in any one of the first areas 11 and the other end of the second wiring 22 may be connected to the first wiring 21 arranged in another adjacent first area 11. That is, the second wiring 22 may be the connection wiring WL (refer to FIG. 5) described above. The second wiring 22 may correspond to the signal line (e.g., the scan line, the data line, etc.) and/or the voltage line (e.g., the first voltage line, the second voltage line, etc.), which provide signals.

According to some embodiments, a modulus of the first wiring 21 may be different from a modulus of the second wiring 22. In particular, the first wiring 21 may have a higher modulus than the second wiring 22. As the second wiring 22 includes a material having a lower modulus than the first wiring 21, the second wiring 22 may relieve high stress when the display device is stretched, thereby reducing stress of the pixel circuit area 13 including the first wiring 21 and relatively improving device stability.

For example, the first wiring 21 may include a metal thin film including a low resistance metal material and the second wiring 22 may include a metal nanostructure and an elastic polymer. The first wiring 21 may include a conductive material including molybdenum (Mo), aluminum (AI), copper (Cu), titanium (Ti), etc. and may include layers or a single layer including the materials described above. For example, the first wiring 21 may be provided as a three-layer metal thin film having a Ti/Al/Ti structure.

The metal nanostructure of the second wiring 22 may include at least one of Ag nanoparticle, Ag nanoflake, or Ag nanowire, and the elastic polymer may include at least one of polydimethylsiloxane (PDMS), polyurethane (PU), or ecoflex. However, embodiments according to the present disclosure are not limited thereto, and both the first wiring 21 and the second wiring 22 may include a metal thin film. Alternatively, the first wiring 21 and the second wiring 22 may include a metal nanostructure and an elastic polymer and may also include materials having different moduli from each other.

Referring to FIG. 9, the first wiring 21 and the second wiring 22 may extend in directions crossing each other. For example, as shown in FIG. 9, the first wiring 21 may extend in the first direction (e.g., the x direction) and the second wiring 22 may extend in the second direction (e.g., the y direction). However, embodiments are not limited thereto, and the first wiring 21 may extend in the second direction (e.g., the y direction) and the second wiring 22 may extend in the first direction (e.g., the x direction).

As the first wiring 21 and the second wiring 22 extend directions crossing each other, the first wiring 21 and the second wiring 22 may each include an overlapping area OA in which the first wiring 21 and the second wiring 22 overlap each other. According to some embodiments, at least one of the first wiring 21 or the second wiring 22 may include an opening OP in the overlapping area OA. In particular, the first wiring 21 may include a first opening 21OP in the overlapping area OA and the second wiring 22 may include a second opening 22OP in the overlapping area OA.

The first opening 21OP and the second opening may extend or be reduced in the direction in which the display apparatus is stretched. In this case, the first opening 21OP and the second opening 22OP may have an elliptical shape, a circular shape, or a rhombus shape in a plane. In particular, when the first opening 21OP and the second opening 22OP have an elliptical shape, the first opening 21OP and the second opening 22OP may be formed such that a long axis of the elliptical shape of each of the first opening 21OP and the second opening 22OP is arranged in a direction in which the wiring that defines the opening OP extends. For example, the first opening 21OP may be formed such that the long axis of the elliptical shape thereof is arranged in the first direction (e.g., the x direction) and the second opening 22OP may be formed such that the long axis of the elliptical shape thereof is arranged in the second direction (e.g., the y direction). In addition, when the first opening 21OP and the second opening 22OP have a rhombus shape, the first opening 21OP and the second opening 22OP may be formed such that a long diagonal among the two horizontals of the rhombus shape thereof is arranged in a direction in which the wiring that defines the opening OP extends. For example, the first opening 21OP may be formed such that the long diagonal of the rhombus shape is arranged in the first direction (e.g., the x direction) and the second opening 22OP may be formed such that the long diagonal of the rhombus shape is arranged in the second direction (e.g., the y direction). This may be to increase the stretchability of a portion where the first wiring 21 is in contact with the second wiring 22 and reduce stress that may be caused during the stretching.

Because the second wiring 22, as the connection wiring WL (refer to FIG. 5), must apply a signal or a voltage to the plurality of pixels, the second wiring 22 needs to be electrically connected to the first wiring 21. According to some embodiments, the first wiring 21 may be electrically connected to the second wiring 22 through a plurality of sub contact holes SCH arranged in an area of the overlapping area OA excluding the opening OP. The plurality of sub contact holes SCH may surround the opening OP in the overlapping area OA.

The first wiring 21 may be electrically connected to the second wiring 22 through two or more sub contact holes SCH. For example, as shown in FIG. 8, four sub contact holes SCH including a first sub contact hole SCH1, a second sub contact hole SCH2, a third sub contact hole SCH3, and a fourth sub contact hole SCH4 may be arranged in the overlapping area OA. In this case, a sum of planar areas of the plurality of sub contact holes SCH may be constant regardless of the number of the plurality of sub contact holes SCH. In particular, when the first wiring 21 is assumed to be connected to the second wiring 22 by one contact hole without the opening OP, the sum of the planar areas of the plurality of sub contact holes SCH may be the same as a planar area of one contact hole. For example, when four sub contact holes SCH are arranged between the first wiring 21 and the second wiring 22 as shown in FIG. 9, the planar area of one sub contact hole SCH may be a quarter of an area of a general contact hole. In some embodiments, when two sub contact holes SCH are arranged between the first wiring 21 and the second wiring 22, the planar area of one sub contact hole SCH may be half the area of a general contact hole.

That is, excellent stretchability of the display apparatus according to some embodiments may be secured as the opening OP is arranged in the overlapping area OA of each wiring. In addition, as the plurality of sub contact holes SCHs are arranged around the opening OP, a contact resistance between the first wiring 21 and the second wiring 22 may be stabilized. In particular, when the display apparatus is stretched, the contact resistance between the first wiring 21 and the second wiring 22 may be greatly increased. In this case, because stress in the display apparatus according to some embodiments may be relieved through the opening OP and distributed by arranging the plurality of sub contact holes SCH, an increase in a contact resistance between the first wiring 21 and the second wiring 22 may be reduced or prevented.

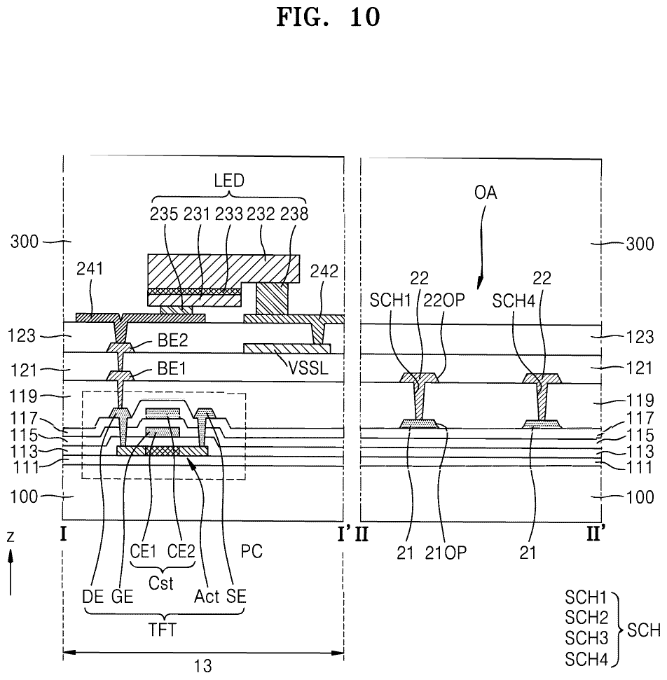

FIG. 10 is a cross-sectional view of a portion of the display apparatus 1 according to some embodiments and corresponds to a cross-section of the display apparatus 1 taken along the line I-I′ of FIG. 8 and the line II-II′ of FIG. 9.

Referring to FIG. 10, the substrate 100 may be a stretchable substrate that may be stretched or reduced in a direction (e.g., a set or predetermined direction). The substrate 100 may include insulating substances such as glass, quartz, and polymer resin. The substrate 100 may include an elastomer. The elastomer may include an organic elastomer, an organic-inorganic elastomer, or a combination thereof. For example, the substrate 100 may include a silicon-based elastomer such as polydimethylsiloxane, a styrene-based elastomer, an olefin-based elastomer, polyurethane, or a mixture thereof. The substrate 100 may have a single-layer or multilayer structure.

A buffer layer 111 may located on the substrate 100 and the pixel circuit PC may be located on the buffer layer 111. The buffer layer 111 may include an organic insulating material, an inorganic insulating material, or an organic-inorganic insulating material and may have a single-layer or multilayer structure.

The thin film transistor TFT may include a semiconductor layer Act, a gate electrode GE, a source electrode SE, and a drain electrode DE. FIG. 10 illustrates a top gate type in which the gate electrode GE is located on the semiconductor layer Act with a gate insulating layer 113 therebetween. However, according to some embodiments, the thin film transistor TFT may be a bottom gate type.

The semiconductor layer Act may include polysilicon. Alternatively, the semiconductor layer Act may include amorphous silicon, an oxide semiconductor, or an organic semiconductor. The gate electrode GE may include a metal thin film including a low-resistance metal material. The gate electrode GE may include a conductive material including Mo, Al, Cu, Ti, etc. and may include layers or a single layer including the materials described above. For example, the gate electrode GE may be provided as a three-layer metal thin film having a Ti/Al/Ti structure.

The gate insulating layer 113 between the semiconductor layer Act and the gate electrode GE may include an organic insulating material, an inorganic insulating material, or an organic-inorganic insulating material and may have a single-layer or multilayer structure.

The source electrode SE and the drain electrode DE may be arranged on the same layer, such as a second interlayer insulating layer 117, and may include the same material. The source electrode SE and the drain electrode DE may include a metal thin film including a low-resistance metal material. The source electrode SE and the gate electrode GE may include a conductive material including Mo, Al, Cu, Ti, etc. and may include layers or a single layer including the materials described above. For example, the source electrode SE and the drain electrode DE may be provided as a three-layer metal thin film having a Ti/Al/Ti structure. The second interlayer insulating layer 117 may include an organic insulating material, an inorganic insulating material, or an organic-inorganic insulating material and may have a single-layer or multilayer structure.

The storage capacitor Cst may include a first electrode CE1 and a second electrode CE2 overlapping each other with a first interlayer insulating layer 115 therebetween. The storage capacitor Cst may overlap the thin-film transistor TFT. In this regard, FIG. 10 illustrates that the gate electrode GE of the thin film transistor TFT is the first electrode CE1 of the storage capacitor Cst. In some embodiments, the storage capacitor Cst may not overlap the thin-film transistor TFT. The storage capacitor Cst may be covered by the second interlayer insulating layer 117.

The first interlayer insulating layer 115 may be arranged between the gate insulating layer 113 and the second interlayer insulating layer 117. The first interlayer insulating layer 115 may include an organic insulating material, an inorganic insulating material, or an organic-inorganic insulating material and may have a single-layer or multilayer structure.

The second electrode CE2 of the storage capacitor CST may include a conductive material and may have a single-layer or multilayer structure. The second electrode CE2 may include a metal thin film including a low-resistance metal material. The second electrode CE2 may include a conductive material including Mo, Al, Cu, Ti, etc. and may include layers or a single layer including the materials described above. For example, the second electrode CE2 may be provided as a three-layer metal thin film having a Ti/Al/Ti structure.

A first organic insulating layer 119 may be located on the second interlayer insulating layer 117 and the second organic insulating layer 121 may be located on the first organic insulating layer 119. The first organic insulating layer 119 and the second organic insulating layer 121 may each include an organic insulating material such as a polyimide.

A first bridge electrode BE1 may be located on the first organic insulating layer 119 and the second bridge electrode BE2 may be located on the second organic insulating layer 121. The first bridge electrode BE1 and the second bridge electrode BE2 may electrically connect the thin film transistor TFT to the light-emitting diode LED. The first bridge electrode BE1 and the second bridge electrode BE2 may include a metal thin film including a low resistance metal material. The first bridge electrode BE1 and the second bridge electrode BE2 may include a conductive material including Mo, Al, Cu, Ti, etc. and may include layers or a single layer including the materials described above. For example, the first bridge electrode and the second bridge electrode BE2 may be provided three-layer metal thin films having a Ti/Al/Ti structure.

The second voltage line VSSL may be located on the second organic insulating layer 121 and the third organic insulating layer 123 may be located on the second organic insulating layer 121 and the second voltage line VSSL. The third organic insulating layer 123 may include an organic insulating material such as a polyimide. The second voltage line VSSL may be connected to the common voltage supply wiring 13 (refer to FIG. 3) to transmit the second power voltage VSS (refer to FIG. 6) to the second electrode 238. According to some embodiments, the second voltage line VSSL, as a connection wiring WL (refer to FIG. 5), may include a different material from the second bridge electrode BE2 which is arranged on the same layer as the second voltage line VSSL. Like the second wiring 22, the second voltage line VSSL may include a material with a lower modulus than the second bridge electrode BE2. For example, the second voltage line VSSL may include a metal nanostructure and an elastic polymer. However, embodiments are not limited thereto, and, in some embodiments, the second voltage line VSSL may include the same material as the second bridge electrode BE2.

The first electrode pad 241 and the second electrode pad 242 may be located on the third organic insulating layer 123. The first electrode pad 241 may be electrically connected to the thin film transistor TFT through the first bridge electrode BE1 between the first organic insulating layer 119 and the second organic insulating layer 121 and the second bridge electrode BE2 between the second organic insulating layer 121 and the third organic insulating layer 123. The light-emitting diode LED on the first electrode pad 241 and the second electrode pad 242 is as described with reference to FIG. 7A. The light-emitting diode LED may be protected by the protective layer 300 and the protective layer 300 may include an inorganic protective layer and/or an organic layer or may an organic material such as resin. FIG. 10 shows that the light-emitting diode LED is an inorganic light-emitting diode described with reference to FIG. 7A, but in some embodiments, the light-emitting diode may be an organic light-emitting diode described with reference to FIG. 7E.

Next, when referring to the overlapping area OA of the first wiring 21 and the second wiring 22, the buffer layer 111, the gate insulating layer 113, the first interlayer insulating layer 115, and the second interlayer insulating layer 117 may be sequentially located on the substrate 100. The first wiring 21 may be located on the second interlayer insulating layer 117. The first wiring 21 may be arranged on the same layer as the source electrode SE and the drain electrode DE and may include the same material as the source electrode SE and the drain electrode DE. For example, the first wiring 21 may include a conductive material including Mo, Al, Cu, Ti, etc. and may include layers or a single layer including the materials described above. The first wiring 21 may be provided as a three-layer metal thin film having a Ti/Al/Ti structure.

The first organic insulating layer 119 may be located on the first wiring 21 and a second wiring 22 may be located on the first organic insulating layer 119. The second organic insulating layer 121 may be located on the second wiring 22. The second wiring 22 may be arranged on the same layer as the first bridge electrode BE1 but may include a different material from the first bridge electrode BE1. According to some embodiments, the second wiring 22 may include a material having a lower modulus than the first wiring 21. In particular, the second wiring 22 may include a metal nanostructure and an elastic polymer. The metal nanostructure may include at least one of an Ag nanoparticle, an Ag nanoflake, or an Ag nanowire. The elastic polymer may include at least one of polydimethylsiloxane (PDMS), polyurethane (PU), or ecoflex.

As described above, the first wiring 21 may include the first opening 21OP in the overlapping area OA. Because the first organic insulating layer 119 may be located on the first wiring 21, the first opening 21OP may be filled with the first organic insulating layer 119. Similarly, the second wiring 22 may include the second opening 22OP in the overlapping area OA and the second opening 22OP may be filled with the second organic insulating layer 121.

In addition, the first wiring 21 may be electrically connected to the second wiring 22 through the plurality of sub contact holes SCH surrounding the opening OP (refer to FIG. 9). According to some embodiments, the plurality of sub contact holes SCH may each penetrate the first organic insulating layer 119. However, embodiments are not limited thereto, and in some embodiments, when the second wiring 22 is arranged on the same layer as the second bridge electrode BE2, the plurality of sub contact holes SCH may each penetrate the first organic insulating layer 119 and the second organic insulating layer 121.

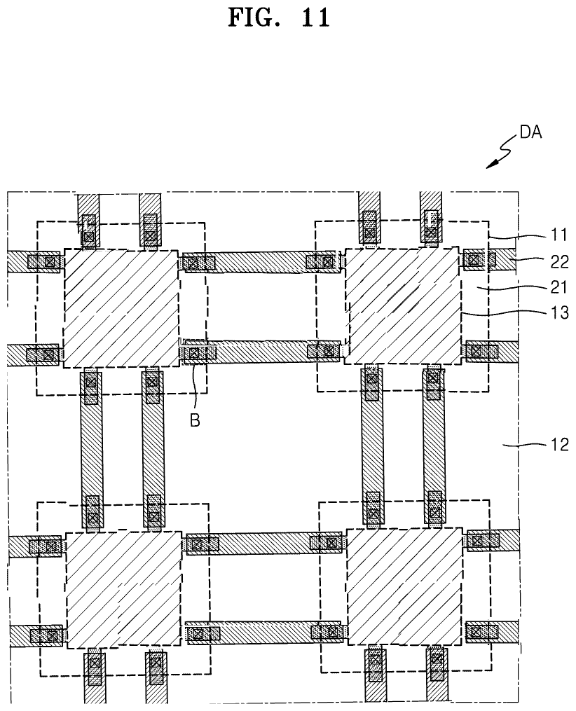

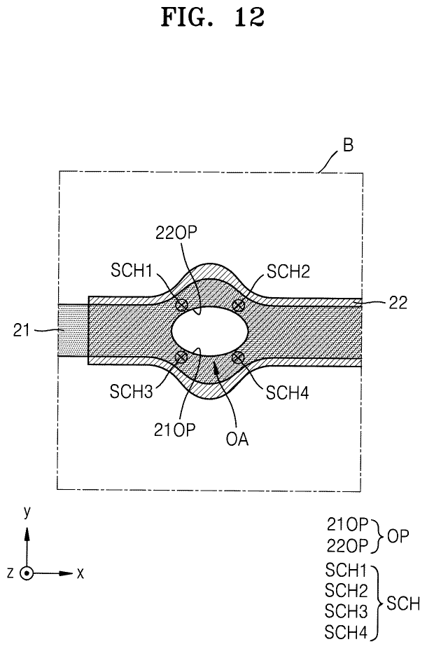

FIG. 11 is a plan view of a portion of the display apparatus according to some embodiments. FIG. 12 is an enlarged plan view of a portion of the display apparatus according to some embodiments and corresponds to area B of FIG. 11. Referring to FIGS. 11 and 12, features other than those of the first wiring 21 and the second wiring 22 are as described in FIGS. 8 to 10. Descriptions of components of FIGS. 11 and 12 having the same reference numbers as those of FIGS. 8 to 10 are substituted with the descriptions of FIGS. 8 to 10 and differences are mainly described below.

Referring to FIGS. 11 and 12, the first wiring 21 and the second wiring 22 located on the first wiring 21 may be arranged in the display area DA. The first wiring 21 may be electrically connected to any one of the plurality of pixel circuits PC (refer to FIG. 6) in the pixel circuit area 13. The second wiring 22, which electrically connects unit pixels that are adjacent to each other, may be the connection wiring WL (refer to FIG. 5).

According to some embodiments, the first wiring 21 and the second wiring 22 may extend in the same direction. The first wiring 21 and the second wiring 22 may include the overlapping area OA in which the first wiring 21 overlaps the second wiring 22. According to some embodiments, the first wiring 21 and the second wiring 22 may each include the opening OP in the overlapping area OA. For example, the first wiring 21 may include the first opening 21OP and the second wiring 22 may include the second opening 22OP.

As described above, the first opening 21OP and the second opening 22OP may extend or contract in the direction in which the display apparatus is stretched. In addition, the first opening 21OP and the second opening 22OP may have an elliptical shape, a circular shape, or a rhombus shape in a plane. When the first wiring 21 and the second wiring 22 extend in the same direction, the first opening 21OP and the second opening 22OP may be arranged side by side such that the long axes of the elliptical shape of the first opening 21OP and the second opening 22OP face the same direction.

Similarly, when the first opening 21OP and the second opening 22OP are arranged side by side, the plurality of sub contact holes SCH may be arranged in an area of the overlapping area OA excluding the opening OP. The plurality of sub contact holes SCH may electrically connect the first wiring 21 to the second wiring 22. Four sub contact holes SCH surrounding the opening OP may be arranged in the overlapping area OA as shown in FIG. 12, but embodiments are not limited thereto, and two or more sub contact holes SCH may be arranged.

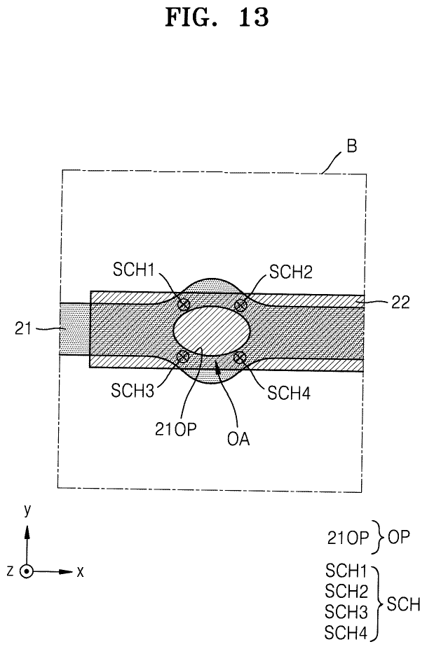

FIG. 13 is an enlarged plan view of a portion of the display apparatus according to some embodiments. Referring to FIG. 13, features other than those of the first wiring 21 and the second wiring 22 are as described in FIGS. 11 and 12. Descriptions of components of FIG. 13 having the same reference numbers as those of FIGS. 11 and 12 are substituted with the descriptions of FIGS. 11 and 12 and differences are mainly described below.

Referring to FIG. 13, the first wiring 21 and the second wiring 22 may extend in the same direction. The first wiring 21 and the second wiring 22 may include the overlapping area OA in which the first wiring 21 overlaps the second wiring 22. According to some embodiments, only one of the first wiring 21 and the second wiring 22 may include an opening OP in the overlapping area OA. For example, as shown in FIG. 13, the first wiring 21 may include the first opening 21OP in the overlapping area OA but the second wiring 22 may not include the opening OP. In other words, the second wiring 22 may be formed integrally with a front surface of the overlapping area OA without the opening.

Similarly, when only the first wiring 21 includes the opening, the plurality of sub contact holes SCH may be arranged in an area of the overlapping area OA excluding the opening OP. The plurality of sub contact holes SCH may electrically connect the first wiring 21 to the second wiring 22. Four sub contact holes SCH surrounding the opening OP may be arranged in the overlapping area OA as shown in FIG. 13, but embodiments are not limited thereto, and two or more sub contact holes SCH may be arranged.

As described above, the first wiring 21 may have a higher modulus than the second wiring 22. In other words, the second wiring 22 may include a material having a higher stretchability than the first wiring 21. For example, the first wiring 21 may include a low-resistant metal thin film material and the second wiring 22 may include a composite material of a metal nanostructure and an elastic polymer. That is, the first opening 21OP is formed in the first wiring 21 with a high modulus, thereby relieving the stress applied to the first area 11 when the wiring is stretched. Because the second wiring 22 is formed with a material with a low modulus, excellent stretchability may be secured without an opening. As a result, the display apparatus according to some embodiments may stabilize the contact resistance between the first wiring 21 and the second wiring 22 while excellent stretchability is secured.

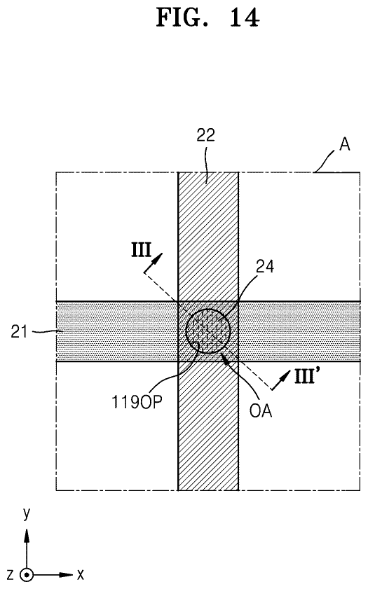

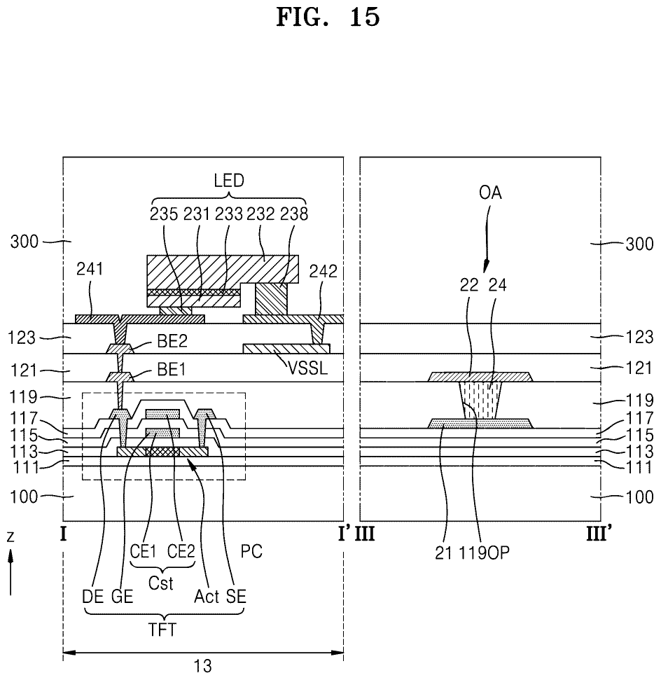

FIG. 14 is an enlarged plan view of a portion of the display apparatus according to some embodiments. FIG. 15 is a cross-sectional view of a portion of the display apparatus 1 according to some embodiments and may correspond to the cross-section of the display apparatus 1 taken along the line I-I′ of FIG. 8 and line III-III′ of FIG. 14. Referring to FIGS. 14 and 15, features other than those of the first wiring 21, the second wiring 22, and the connection material 24 are as described in FIGS. 8 to 10. Descriptions of components of FIGS. 14 and 15 having the same reference numbers as those of FIGS. 8 to 10 are substituted with the descriptions of FIGS. 8 to 10 and differences are mainly described below.

Referring to FIGS. 14 and 15, the first wiring 21 and the second wiring 22 located on the first wiring 21 may be arranged in the display area DA. The first wiring 21 may be electrically connected to any one of the plurality of pixel circuits PC (refer to FIG. 6) in the pixel circuit area 13. The second wiring 22, which electrically connects unit pixels that are adjacent to each other, may be the connection wiring WL (refer to FIG. 5).

According to some embodiments, the first wiring 21 and the second wiring 22 may include the same material. In particular, the first wiring 21 may be arranged on the same layer as the source electrode SE and the drain electrode DE and may include the same material as the source electrode SE and the drain electrode DE. The second wiring 22 may be arranged on the same layer as the first bridge electrode BE1 and include the same material as the first bridge electrode BE1. That is, the first wiring 21 and the second wiring 22 may include a metal thin film including a low resistance metal material. For example, the first wiring 21 and the second wiring 22 may include a conductive material including Mo, Al, Cu, Ti, etc. and may include layers or a single layer including the materials described above. However, embodiments are not limited thereto, and in some embodiments, the first wiring 21 may have a higher modulus than the second wiring 22. For example, the first wiring 21 may include a metal thin film and the second wiring 22 may include a composite material of a metal nanostructure and an elastic polymer.

Referring to FIGS. 14 and 15, the first wiring 21 and the second wiring 22 may not include the opening OP (refer to FIG. 9) in the overlapping area OA and may not be connected to each other through the plurality of sub contact holes SCH (refer to FIG. 9). However, in the display apparatus according to some embodiments, the connection material 24 may be arranged between the first wiring 21 and the second wiring 22. In particular, the first organic insulating layer 119 arranged between the first wiring 21 and the second wiring 22 may include an insulating layer opening 119OP overlapping the overlapping area OA and the connection material 24 may be arranged in the insulating layer opening 119OP. As the insulating layer opening 119OP penetrates the first organic insulating layer 119, the connection material 24 may be in direct contact with an upper surface of the first wiring 21 and a lower surface of the second wiring 22. The first wiring 21 may be electrically connected to the second wiring 22 through a conductive connection material 24 instead of a contact hole.

In this case, the connection material 24 may have a lower modulus than each of the first wiring 21 and the second wiring 22. According to some embodiments, the connection material 24 may include a liquid metal. For example, the connection material 24 may include a liquid metal including eutectic gallium-indium alloy (EGaln) or gallium-indium-tin alloy (Galinstan). That is, the connection material 24 may include at least one of gallium (Ga), indium (In), or tin (Sn). In particular, the eutectic Ga-In (EGaln), which is a eutectic alloy of Ga and In, has a lower melting point than room temperature, and thus may be in a liquid state at room temperature and have a low resistivity.

That is, the display apparatus according to some embodiments may have excellent stretchability because the first wiring 21 is connected to the second wiring 22 with the connection material 24. In addition, because the connection material 24 includes a liquid material with a low modulus, the contact resistance between the first wiring 21 and the second wiring 22 may be stabilized. In general, when the display apparatus is stretched, the contact resistance between the first wiring 21 and the second wiring 22 may be greatly increased. In this case, when a liquid metal having a low modulus is arranged between the first wiring 21 and the second wiring 22, because the connection material 24 may relieve the stress even when the display device is stretched, the first wiring 21 may be stably connected to the second wiring 22 and the contact resistance may be reduced.

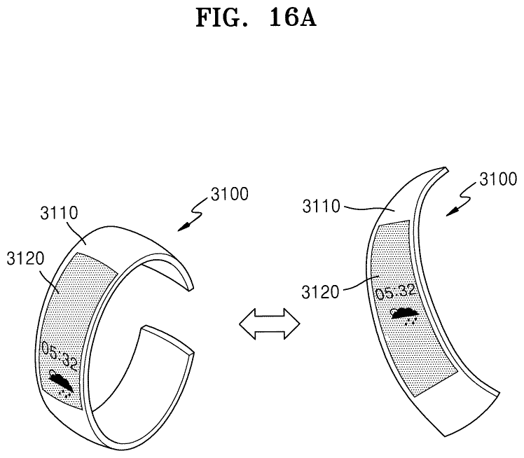

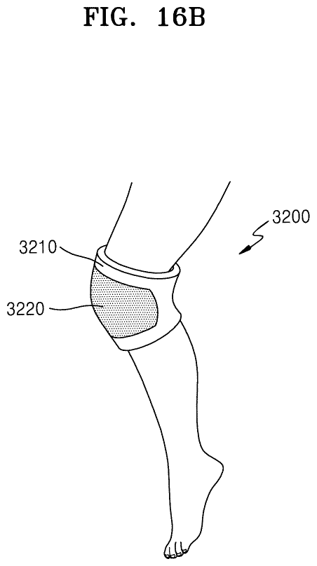

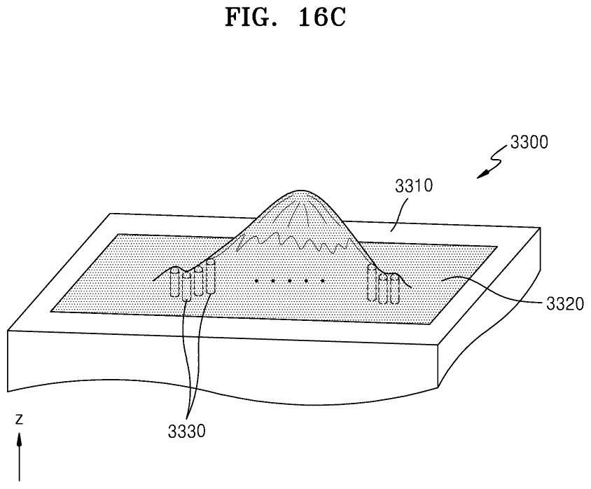

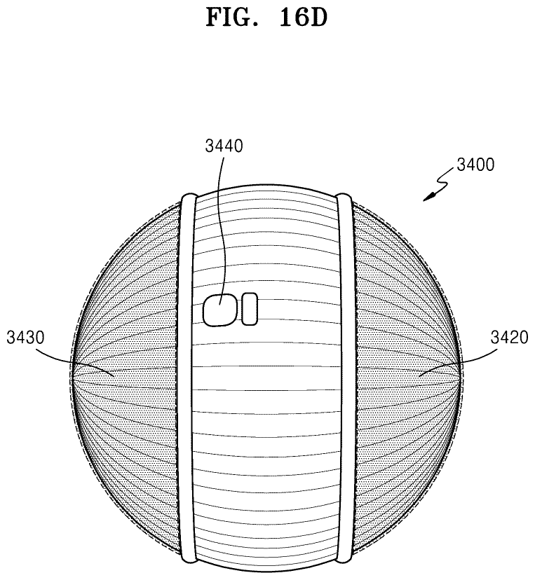

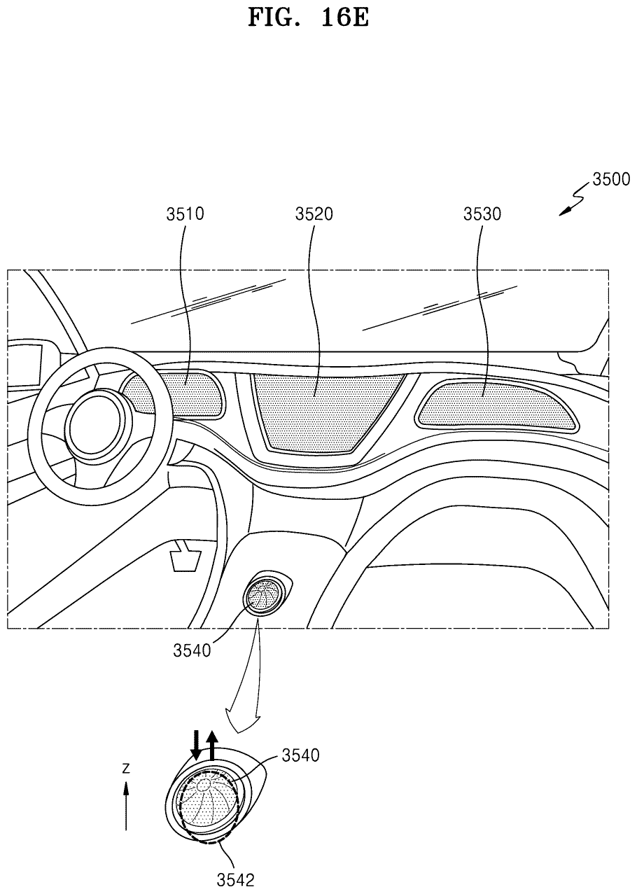

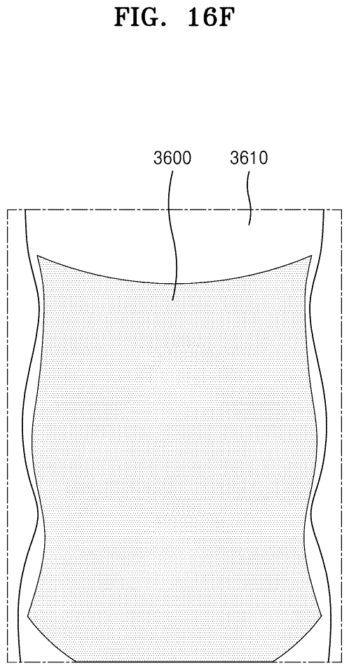

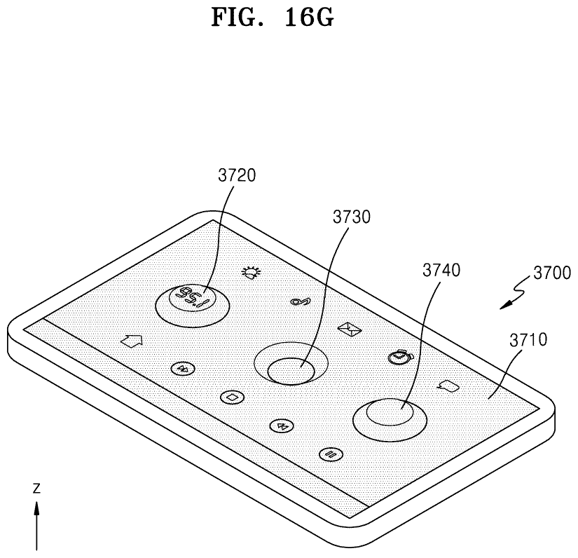

FIGS. 16A to 16G are perspective views schematically illustrating embodiments of an electronic device including the display apparatus according to some embodiments.

Referring to FIG. 16A, the display apparatus according to some embodiments may be used for wearable electronic devices 3100 that may be worn on any part of the body. The wearable electronic device 3100 may include a body portion 3110 and a display portion 3120 included in the body portion 3110. The display apparatus according to some embodiments may be used as the display portion 3120 of the wearable electronic device 3100. The wearable electronic device 3100 may be modified. According to some embodiments, the wearable electronic device 3100 may be used as a smartwatch or a smartphone according to the user's choice.

FIG. 16B illustrates a medical electronic device 3200. According to some embodiments, the medical electronic device 3200 may include a body portion 3210 and a light-emitting portion 3220. The display apparatus according to some embodiments may be used as the light-emitting portion 3220 of the medical electronic device 3200.

The light-emitting portion 3220 may emit light (e.g., infrared ray, visible light, etc.) of a certain wavelength band to the body of a patient. According to some embodiments, the body portion 3210 may have a stretchable fiber material and may have a structure that may be worn on the body of the user.

FIG. 16C shows an educational electronic device 3300. According to some embodiments, the educational electronic device may include a display portion 3320 included in a frame 3310. The display portion 3320 may use the display apparatus according to the embodiments. The display portion 3320 may provide an image such as the sea with waves, a mountain covered with snow, or a volcano with lava flowing thereon, and the display portion 3320 may be stretched in the height direction (e.g., the z direction) to reflect the height of the waves, mountains, or volcanoes. In some embodiments, a portion of the display portion 3320 may three-dimensionally show the movement of lava by sequentially varying the height thereof according to the direction in which the lava flows. The educational electronic device 3300 may include a plurality of pins (or stroke portions 3330) arranged on a rear surface of the display portion 3320 such that the display portion 3320 is stretched in the height direction. The pins 3330 may be implemented to move in the third direction (e.g., the z direction or the-z direction) such that the image expressed by the display portion 3320 has a three-dimensional height. FIG. 16C illustrates an educational electronic device 3300, but the usage thereof is not limited as long as it provides image information (e.g., set or predetermined image information).

FIGS. 16A to 16C illustrate electronic devices of which the shape may be modified, but the disclosure is not limited thereto. As described in the embodiments below, the display apparatus according to embodiments may be used in an electronic device of which an area that may express an image (e.g., screen) is fixed.

FIG. 16D shows a robot 3400 as another electronic device according to some embodiments. The robot 3400 may detect a movement or an object by using a camera portion 3440 and may display an image (e.g., a set or predetermined image) to a user through display portions 3420 and 3430. In some embodiments, because the display apparatuses according to some embodiments may be stretched in various directions as described above, the display apparatuses may be assembled to a body frame having a hemispherical shape, and thus, the robot 3400 may include hemispherical display portions 3420 and 3430.

FIG. 16D shows a vehicle display device 3500 as another electronic device according to some embodiments. The vehicle display device 3500 may include a cluster 3510, a center information display (CID) 3520, and/or a passenger display. Because the display apparatus according to some embodiments may be stretched in various directions, the display apparatus may be used in the cluster 3510, CID 3520, and/or a co-driver display without being bounded by the shape of an inner frame of the vehicle.

FIG. 16E illustrates that each of the cluster 3510, the CID 3520, and/or the co-driver display is separated, but the disclosure is not limited thereto. In some embodiments, at least two selected from the cluster 3510, the CID 3520, and the co-driver display may be integrally connected to each other.

In some embodiments, the vehicle display device 3500 may include a button 3540 that may express an image (e.g., a set or predetermined image). Referring to an enlarged view of FIG. 16E, the hemispherical button 3540 may include an object 3542 moving in the z direction or the-z direction to provide feeling of the button and a display apparatus located on the object 3542. In some embodiments, when the object 3542 has a three-dimensionally round surface, the display apparatus may also have a three-dimensionally round surface.

FIG. 16F illustrates that the electronic device according to some embodiments is an electronic device 3600 for advertising or exhibition. In some embodiments, the electronic device 3600 for advertising or exhibition may be installed in a fixed structure 3610, such as a wall or pillar. When the structure 3610 includes an uneven surface as shown in FIG. 13F, the electronic device 3600 for advertising or exhibition may be arranged along the uneven surface of the structure 3610. In some embodiments, the electronic device 3600 for advertising or exhibition may be installed in the structure 3610 by using a thermal-shrinking film, etc.

FIG. 16G shows a controller 3700 as an electronic device according to some embodiments. The controller 3700 may include an image-type button. For example, the controller 3700 may include first to third button areas 3720, 3730, and 3740, which are a portion of the display portion 3710 protruding in the z direction (or being submerged in the-z direction). In some embodiments, the first and third button areas 3720 and 3740 may protrude in the z direction and the second button area 3730 may protrude in the-z direction (or be submerged in the z direction).

The display apparatus according to some embodiments may have relatively excellent stretchability and may relatively reduce the contact resistance between the wirings when stretched.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate;
a first wiring on the substrate; and
a second wiring on the first wiring and electrically connected to the first wiring, wherein
the first wiring and the second wiring comprise an overlapping area in which the first wiring overlaps the second wiring in a plan view, and
at least one of the first wiring or the second wiring comprises an opening in the overlapping area.

2. The display apparatus of claim 1, wherein the first wiring and the second wiring are electrically connected to each other through a plurality of sub contact holes arranged in an area of the overlapping area excluding the opening.

3. The display apparatus of claim 2, further comprising:
a first insulating layer between the first wiring and the second wiring; and
a second insulating layer on the second wiring, wherein
the first insulating layer fills the opening of the first wiring, and
the second insulating layer fills the opening of the second wiring.

4. The display apparatus of claim 3, wherein the plurality of sub contact holes penetrate the first insulating layer.

5. The display apparatus of claim 2, wherein a sum of planar areas of the plurality of sub contact holes is constant regardless of a number of the plurality of sub contact holes.

6. The display apparatus of claim 2, wherein a sum of planar areas of the plurality of sub contact holes is equal to a planar area of a contact hole to which the first wiring and the second wiring are electrically connectable without the opening.

7. The display apparatus of claim 1, wherein the opening has an elliptical, circular, or rhombus shape in the plan view.

8. The display apparatus of claim 7, wherein the opening has an elliptical shape and the opening is arranged such that a long axis of the elliptical shape is arranged in a direction in which a wiring defining the opening extends.

9. The display apparatus of claim 7, wherein the opening has a rhombus shape and the opening is arranged such that a long diagonal of two diagonals of the rhombus shape is arranged in a direction in which a wiring defining the opening extends.

10. The display apparatus of claim 1, wherein the first wiring has a higher modulus than the second wiring.

11. The display apparatus of claim 10, wherein each of the first wiring and the second wiring comprises the opening in the overlapping area.

12. The display apparatus of claim 10, wherein the first wiring includes the opening in the overlapping area and the second wiring is integrally formed with the overlapping area without the opening.

13. The display apparatus of claim 1, further comprising:
a plurality of pixel circuits on the substrate;
a plurality of light-emitting elements respectively and electrically connected to the plurality of pixel circuits; and
a bridge electrode connecting one of the plurality of light-emitting elements to one of the plurality of pixel circuits.

14. The display apparatus of claim 13, wherein
the first wiring is arranged on a same layer as a source electrode or a drain electrode included in the plurality of pixel circuits, and
the second wiring is arranged on the same layer as the bridge electrode.

15. The display apparatus of claim 13, wherein
the first wiring is electrically connected to one of the plurality of pixel circuits, and
the second wiring electrically connects adjacent pixel circuits from among the plurality of pixel circuits.

16. A display apparatus comprising:
a substrate;
a first wiring on the substrate;
an insulating layer on the first wiring; and
a second wiring on the insulating layer, wherein
the first wiring and the second wiring include an overlapping area in which the first wiring overlaps the second wiring in a plane,
the insulating layer includes an opening overlapping the overlapping area, and
a connection material having a different modulus from each of the first wiring and the second wiring is arranged in the opening of the insulating layer.

17. The display apparatus of claim 16, wherein the connection material has a lower modulus than each of the first wiring and the second wiring.

18. The display apparatus of claim 16, wherein the connection material includes a liquid metal.

19. The display apparatus of claim 18, wherein the liquid metal includes eutectic gallium-indium alloy (EGaln) or gallium-indium-tin alloy (Galinstan).

20. The display apparatus of claim 16, wherein
the connection material is in contact with an upper surface of the first wiring and a lower surface of the second wiring, and
electrically connects the first wiring to the second wiring.

21. The display apparatus of claim 16, further comprising:
a plurality of pixel circuits on the substrate;
a plurality of light-emitting elements respectively and electrically connected to the plurality of pixel circuits; and
a bridge electrode connecting one of the plurality of light-emitting elements to one of the plurality of pixel circuits.

22. The display apparatus of claim 21, wherein
the first wiring is on a same layer as a source electrode or a drain electrode included in the plurality of pixel circuits, and
the second wiring is on the same layer as the bridge electrode.

23. The display apparatus of claim 21, wherein
the first wiring is electrically connected to one of the plurality of pixel circuits, and
the second wiring electrically connects adjacent pixel circuits from among the plurality of pixel circuits.
